(19) United States
(12) Patent Application Publication
(10) Pub. No.: US 2024/0345467 A1
(43) Pub. Date: Oct. 17, 2024

(54) BLANK MASK AND METHOD OF FABRICATING THE SAME

(71) Applicant: SK enpulse Co., Ltd., Gyeonggi-do (KR)

(72) Inventors: Tae Wan KIM, Seoul (KR); Geon Gon LEE, Seoul (KR); Min Gyo JEONG, Seoul (KR); Hyung Joo LEE, Seoul (KR); Tae Young KIM, Seoul (KR)

(21) Appl. No.: 18/638,000

(22) Filed: Apr. 17, 2024

(30) Foreign Application Priority Data
Apr. 17, 2023 (KR) 10-2023-0050359

(51) Int. Cl. G03F 1/26; G03F 1/82

(52) U.S. Cl. CPC G03F 1/26; G03F 1/82

(57) ABSTRACT

A method of fabricating a blank mask, the method including: forming a light-shielding film on a light-transmissive substrate; and cleaning the light-shielding film with a cleaning solution, wherein in the cleaning, the light-shielding film has a thickness change of less than 5 nm. The blank mask may include a light-transmissive substrate and a light-shielding film disposed on the light-transmissive substrate. Further, on an entire surface of the blank mask, a content of halogen ions is less than 0.05 ng/cm², a content of nitrogen-based ions is less than 2 ng/cm², and a content of sulfur-based ions is less than 0.1 ng/cm². The blank mask may be a photomask.

### CROSS-REFERENCE TO RELATED APPLICATIONS

This application claims priority under 35 U.S.C. § 119 to Korean Patent Application No. 10-2023-0050359 filed on Apr. 17, 2023 in the Korean Intellectual Property Office, the disclosure of which is incorporated herein by reference in its entirety.

### BACKGROUND

### Technical Field

Embodiments relate to a blank mask and a method of fabricating the same.

### Background Art

Due to the high integration of semiconductor devices, etc., there is a demand for refinement of circuit patterns of semiconductor devices. Thereby, the importance of lithography technology, a technology that develops circuit patterns on the surface of a wafer using a photomask, is attracting more attention.

To develop refined circuit patterns, a shorter wavelength of the exposure light source used in an exposure process is required. As examples of exposure light sources recently used, there is an argon fluoride (ArF) excimer laser (wavelength: 193 nm), and the like.

Meanwhile, a photomask includes a binary mask, a phase shift mask, and the like.

A binary mask includes a light-shielding layer pattern formed on a light-transmissive substrate. On the surface, where patterns are formed, of a binary mask, a light transmission part excluding a light-shielding layer transmits exposure light, and a light-shielding part including a light-shielding layer blocks the exposure light, exposing a pattern on a resist film of a wafer surface. Meanwhile, issues can occur in the fine pattern phenomenon due to light diffraction that occurs at the edges of a light transmission part during an exposure process as the pattern of a binary mask becomes finer.

As examples of a phase shift mask, there are a Levenson-type mask, an outrigger-type mask, and a half tone-type mask. Among these, a half tone-type phase shift mask has a pattern, which is made of a semi-transmissive film, formed on a light-transmissive substrate 10. On the patterned surface of the half tone-type phase shift mask, a light transmission part (excluding a semi-transmissive layer} transmits exposure light, and a semi-transmissive part (including a semi-transmissive layer) transmits attenuated exposure light. The attenuated exposure light has a phase difference compared to the exposure light that passed through the light transmission part. Accordingly, diffracted light occurring at the edge of the light transmission part is canceled out by exposure light transmitted through the semi-transmissive part, so that the phase shift mask can form a more elaborate fine pattern on a wafer surface.

Related documents are as follows:
(Patent Document 0001) Korean Patent Application Publication No. 10-2012-0057488
(Patent Document 0002) Korean Patent Application Publication No. 10-2014-0130420

### SUMMARY

Therefore, the present invention has been made in view of the above issues, and it is one object of the present invention to provide an apparatus for fabricating a blank mask that can provide a photomask having low defect occurrence, improved number of uses, and high precision, and can provide a method of fabricating the blank mask.

In accordance with one aspect of the present invention, there is provided a method of fabricating a blank mask, the method including: forming a light-shielding film on a light-transmissive substrate; and cleaning the light-shielding film with a cleaning solution, wherein in the cleaning, the light-shielding film has a thickness change of less than 15 nm.

In the method of fabricating a blank mask according to one embodiment, the method may further include forming a phase shift film on the light-transmissive substrate, wherein the light-shielding film is formed on the phase shift film.

In the method of fabricating a blank mask according to another embodiment, on an entire surface of the blank mask, a content of halogen ions may be less than 0.1 ng/cm², a content of nitrogen-based ions may be less than 3 ng/cm², and a content of sulfur-based ions may be less than 0.1 ng/cm².

In the method of fabricating a blank mask according to another embodiment, the halogen ions may include chlorine-based ions, the nitrogen-based ions may include nitrite ions, nitrate ions and ammonia, and the sulfur-based ions may include sulfate ions.

In the method of fabricating a blank mask according to another embodiment, the cleaning solution may include carbonated water.

In the method of fabricating a blank mask according to another embodiment, in the cleaning, the light-shielding film may have a transmittance change of less than 0.05%.

In the method of fabricating a blank mask according to another embodiment, in the cleaning, the light-shielding film may have an optical density change of less than 0.07.

In the method of fabricating a blank mask according to another embodiment, in the cleaning, the light-shielding film may have a reflectance change of less than 0.5%.

In the method of fabricating a blank mask according to another embodiment, in the cleaning, the light-shielding film may have a thickness change ranging from 0.3 nm to 3 nm.

In the method of fabricating a blank mask according to another embodiment, the light-shielding film may include: a first light-shielding layer disposed on the light-transmissive substrate; and a second light-shielding layer disposed on the first light-shielding layer, wherein the second light-shielding layer includes a nitrogen element in a content ranging from 20 atom % to 40 atom %, a chromium element in a content ranging from 30 atom % to 50 atom % and an oxygen element in a content ranging from 20 atom % to 40 atom %.

In the method of fabricating a blank mask according to another embodiment, the first light-shielding layer may include a nitrogen element in a content ranging from 10 atom % to 30 atom %, a chromium element in a content ranging from 60 atom % to 90 atom % and an oxygen element in a content ranging from 0.5 atom % to 10 atom %.

In the method of fabricating a blank mask according to another embodiment, the second light-shielding layer may include a carbon element in a content of less than 5 atom %.

In accordance with another aspect of the present invention, there is provided a blank mask, including: a light-transmissive substrate; and a light-shielding film disposed on the light-transmissive substrate, wherein on an entire surface of the blank mask, a content of halogen ions is less than 0.05 ng/cm², a content of nitrogen-based ions is less than 2 ng/cm², and a content of sulfur-based ions is less than 0.1 ng/cm².

In the blank mask according to another embodiment, a thickness change in the light-shielding film measured by a measurement method below may be less than 15 nm, wherein in the measurement method the light-shielding film is immersed for 10 minutes in carbonated water with a carbonate concentration of 2000 mg/C, and a thickness change in the light-shielding film is a difference between a thickness of the light-shielding film before immersion and a thickness of the light-shielding film after immersion.

In the blank mask according to another embodiment, the light-shielding film may have a transmittance change of less than 0.05%, the light-shielding film may have an optical density change of less than 0.07, and the light-shielding film may have a reflectance change of less than 0.5%, the transmittance change is a difference between a transmittance of the light-shielding film before immersion and a transmittance of the light-shielding film after immersion, the optical density change is a difference between an optical density of the light-shielding film before immersion and an optical density of the light-shielding film after immersion, and the reflectance change is a difference between a reflectance of the light-shielding film before immersion and a reflectance of the light-shielding film after immersion.

In the blank mask according to another embodiment, the light-shielding film may include: a first light-shielding layer disposed on the light-transmissive substrate; and a second light-shielding layer disposed on the first light-shielding layer, wherein the second light-shielding layer includes a nitrogen element in a content ranging from 20 atom % to 40 atom %, a chromium element in a content ranging from 30 atom % to 50 atom % and an oxygen element in a content ranging from 20 atom % to 40 atom %.

In the blank mask according to another embodiment, the first light-shielding layer may include a nitrogen element in a content ranging from 10 atom % to 30 atom %, a chromium element in a content ranging from 60 atom % to 90 atom % and an oxygen element in a content ranging from 0.5 atom % to 10 atom %.

In the blank mask according to another embodiment, the light-shielding film may have a thickness change ranging from 0.3 nm to 3 nm.

In the blank mask according to another embodiment, the light-shielding film may have a thickness change ranging from 0.1 nm to 1 nm.

In accordance with yet another aspect of the present invention, there is provided a photomask, including: a light-transmissive substrate; and a light-shielding film disposed on the light-transmissive substrate, wherein on an entire surface of the photomask, a content of halogen ions is less than 0.05 ng/cm², a content of nitrogen-based ions is less than 2 ng/cm², and a content of sulfur-based ions is less than 0.1 ng/cm².

In a cleaning step of a method of fabricating a blank mask according to another embodiment, a thickness change is minimized. In addition, a transmittance change in the cleaning step of the method of fabricating a blank mask according to another embodiment can be minimized. In the cleaning step of the method of fabricating a blank mask according to another embodiment, a change in an optical density can be minimized. In the cleaning step of the method of fabricating a blank mask according to another embodiment, a reflectance change can be minimized.

By the method of fabricating a blank mask according to another embodiment, an ion concentration on the surface of a blank mask can be lowered. The concentrations of halogen ions, nitrogen-based ions and sulfur-based ions on the surface of the blank mask according to another embodiment can be lowered.

In the method of fabricating a blank mask according to another embodiment, the cleaning solution can include carbonated water. Therefore, in the cleaning step of the method of fabricating a blank mask according to another embodiment, the concentrations of halogen ions, nitrogen ions and sulfur-based ions can be reduced while minimizing a thickness change, a transmittance change, an optical density change and a reflectance change.

### BRIEF DESCRIPTION OF DRAWINGS

FIG. 1 is a sectional view illustrating a cross-section of a blank mask according to one embodiment.

FIG. 2 is a sectional view illustrating a cross-section of a blank mask according to another embodiment.

FIG. 3 is a sectional view illustrating a cross-section of a blank mask according to still another embodiment.

FIG. 4 is a sectional view illustrating a cross-section of a photomask according to one embodiment.

FIG. 5 illustrates a process of cleaning the blank mask according to another embodiment.

### DETAILED DESCRIPTION

Hereinafter, embodiments will be described in detail such that those skilled in the art can make and used the invention. However, the embodiments may be implemented in various different forms and the present invention is not limited to embodiments described herein.

The terms “about,” “substantially,” and the like used in this specification are used to mean at or close to a presented numerical value when manufacturing and material tolerances in the stated meaning provided to aid understanding of the embodiments.

Throughout this specification, the term “a combination thereof” refers to a mixture or combination of one or more elements selected from the group consisting of components, and to include one or more selected from the group consisting of the components.

Throughout this specification, the expression “A and/or B” means “A, B, or A and B”.

In this specification, “B is located on A” means “B is located on A” or “B is located on A with another layer located therebetween”, and is not interpreted as limited to B being positioned in contact with the surface of A.

In this specification, singular expressions are interpreted to include singular or plural as interpreted in context, unless otherwise specified.

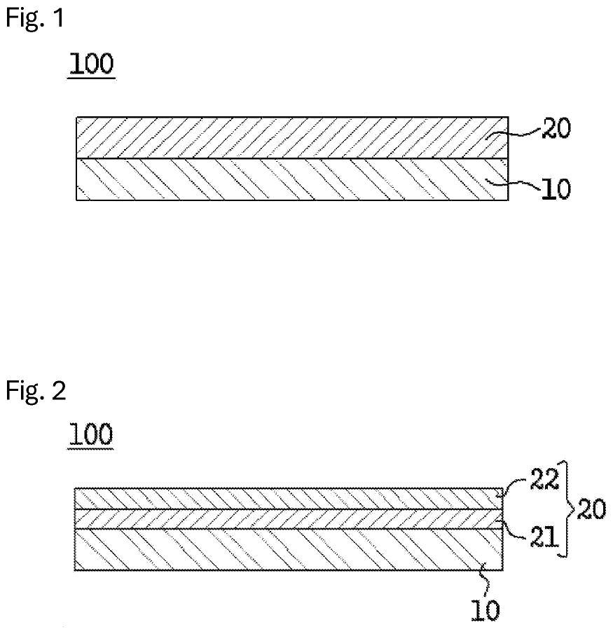

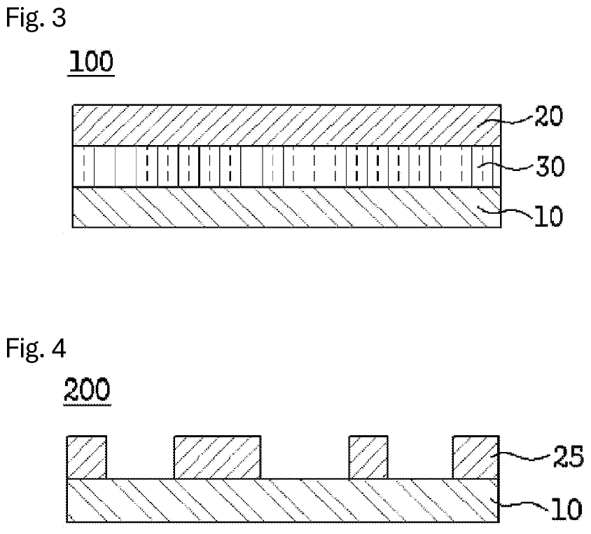

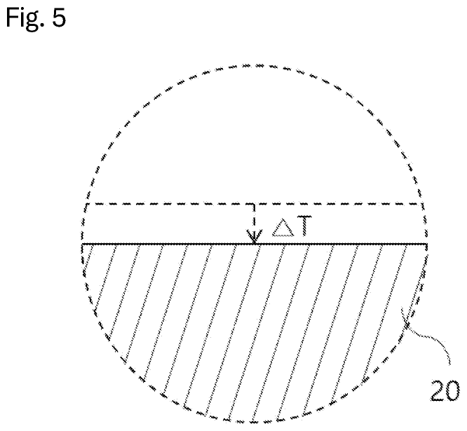

FIG. 1 is a sectional view illustrating a cross-section of a blank mask according to one embodiment. FIG. 2 is a sectional view illustrating a cross-section of a blank mask according to another embodiment. FIG. 3 is a sectional view illustrating a cross-section of a blank mask according to still another embodiment. FIG. 4 is a sectional view illustrating a cross-section of a photomask according to an embodiment. FIG. 5 illustrates a process of cleaning a blank mask according to still another embodiment.

A blank mask 100 according to one embodiment includes a light-transmissive substrate 10; and a light-shielding film 20 disposed on the light-transmissive substrate 10.

The light-transmissive substrate 10 may have optical transparency to exposure light. The light-transmissive substrate 10 may have a transmittance of greater than about 85% for exposure light having a wavelength of about 193 nm. The transmittance of the light-transmissive substrate 10 may be greater than about 87%. The transmittance of the light-transmissive substrate 10 may be less than 99.99%. The light-transmissive substrate 10 may include a synthetic quartz substrate. In this case, the light-transmissive substrate 10 may suppress the attenuation of transmitted light.

Since the light-transmissive substrate 10 has surface characteristics such as appropriate flatness and appropriate illuminance, it may suppress distortion of transmitted light.

The light-shielding film 20 may be disposed on a top side of the light-transmissive substrate 10.

The light-shielding film 20 may at least selectively block exposure light incident on a bottom side of the light-transmissive substrate 10.

In addition, when a phase shift film 30, etc. is disposed between the light-transmissive substrate 10 and the light-shielding film 20 as shown in FIG. 3, the light-shielding film 20 may be used as an etching mask in a process of etching the phase inversion film 30, etc., according to a pattern shape.

The light-shielding film 20 may include a transition metal and include at least one of oxygen and nitrogen.

The light-shielding film 20 may include chromium, oxygen, nitrogen and carbon. The content of each element in the entire light-shielding film 20 may vary in the thickness direction. The content of each element in the entire light-shielding film 20 may differ by layer in the case of a multi-layered light-shielding film 20.

The light-shielding film 20 may include chromium in a content of about 44 atom % to about 60 atom %. The light-shielding film 20 may include chromium in a content of about 47 atom % to about 57 atom %.

The light-shielding film 20 may include carbon in a content of about 5 atom % to 30 atom %. The light-shielding film 20 may include carbon in a content of about 7 atom % to about 25% atom %.

The light-shielding film 20 may include nitrogen in a content of about 3 atom % to about 20 atom %. The light-shielding film 20 may include nitrogen in a content of about 5 atom % to about 15 atom %.

The light-shielding film 20 may include oxygen in a content of about 20 atom % to about 45 atom %. The light-shielding film 20 may include oxygen in a content of about 25 atom % to about 40 atom %.

An upper part of the upper part of the light-shielding film 20 may include a nitrogen element in a content of about 6 atom % to about 16 atom %, a chromium element in a content of about 26 atom % to about 46 atom %, an oxygen element in a content of about 37 atom % to about 47 atom % and a carbon element in a content of about 4 atom % to about 14 atom %.

The upper part of the light-shielding film 20 may include a nitrogen element in a content of about 16 atom % to about 26 atom %, a chromium element in a content of about 28 atom % to about 40 atom %, an oxygen element in a content of about 27 atom % to about 37 atom % and a carbon element in a content of about 3 atom % to about 13 atom %.

The upper part of the light-shielding film 20 may include a nitrogen element in a content of about 18 atom % to about 27 atom %, a chromium element in a content of about 35 atom % to about 41 atom %, an oxygen element in a content of about 31 atom % to about 41 atom % and a carbon element in a content of about 1 atom % to about 4 atom %.

The upper part of the light-shielding film 20 can be defined as from the top surface of the light-shielding film 20 to a depth of ⅛ based on the total thickness of the light-shielding film 20. That is, in this embodiment, considering the total thickness of the light-shielding film 20 as 8, the upper part of the light-shielding film 20 may mean a depth of 1 from the top surface of the light-shielding film 20. However, the present disclosure is not limited to this depth characteristic.

In addition, the content of the nitrogen element in the upper part of the light-shielding film 20 may gradually increase. In the upper part of the light-shielding film 20, the content of the nitrogen element may gradually increase from one of about 15 atom % to about 25 atom %. Here, a difference between the minimum and maximum content of the nitrogen element in the upper part of the light-shielding film 20 may be about 3 atom % to about 8 atom %.

In addition, the content of the chromium element in the upper part of the light-shielding film 20 may gradually increase. In the upper part of the light-shielding film 20, the content of the chromium element may gradually increase from one of about 30 atom % to about 40 atom %. Here, a difference between the minimum and maximum content of the chromium element in the upper part of the light-shielding film 20 may range from about 3 atom % to about 8 atom %.

In addition, the content of the carbon element in the upper part of the light-shielding film 20 may gradually decrease. In the upper part of the light-shielding film 20, the content of the carbon element may gradually decrease from one of about 1 atom % to about 7 atom %. Here, a difference between the minimum and maximum content of the carbon element in the upper part of the light-shielding film 20 may range from about 0.5 atom % to about 5 atom %.

In addition, the content of the oxygen element in the upper part of the light-shielding film 20 may gradually decrease. In the upper part of the light-shielding film 20, the content of the oxygen element may gradually decrease from one of about 35 atom % to about 45 atom %. Here, a difference between the minimum and maximum content of the oxygen element in the upper part of the light-shielding film 20 may range from about 4 atom % to about 14 atom %.

In one embodiment, the light-shielding film 20 may have sufficient extinction properties to attenuate substantially all transmission of for example light having a wavelength of about 193 nm though the light-shielding film 20.

As shown in FIG. 2, the light-shielding film 20 may include a first light-shielding layer 21; and a second light-shielding layer 22 disposed on the first light-shielding layer 21.

The second light-shielding layer 22 includes a transition metal. In addition, the second light-shielding layer 22 may include at least one of oxygen, nitrogen and carbon. The second light-shielding layer 22 may include a transition metal in a content ranging from about 50 atom % to about 80 atom %. The second light-shielding layer 22 may include a transition metal in a content ranging from about 55 atom % to about 75 atom %. The second light-shielding layer 22 may include a transition metal in a content ranging from about 60 atom % to about 70 atom %.

In the second light-shielding layer 22, the content of an element corresponding to at least one of oxygen, nitrogen and carbon may range from about 10 atom % to about 35 atom %. In the second light-shielding layer 22, the content of an element corresponding to at least one of oxygen, nitrogen and carbon may range from about 15 atom % to about 25 atom %.

The second light-shielding layer 22 may include nitrogen in a content ranging from about 5 atom % to about 20 atom %. The second light-shielding layer 22 may include nitrogen in a content ranging from about 7 atom % to about 13 atom %.

The second light-shielding layer 22 may include oxygen in a content ranging from about 5 atom % to about 20 atom %. The second light-shielding layer 22 may include oxygen in a content ranging from about 7 atom % to about 13 atom %.

The second light-shielding layer 22 may include carbon in a content ranging from about 2 atom % to about 10 atom %. The second light-shielding layer 22 may include nitrogen in a content ranging from about 37 atom % to about 8 atom %.

The second light-shielding layer 22 may include all of the elements including nitrogen, oxygen and carbon therein.

In one embodiment, the light-shielding film 20 may form a laminate with the phase shift film 30 to help substantially block exposure light.

The first light-shielding layer 21 may include a transition metal. The first light-shielding layer 21 may include oxygen and nitrogen. The first light-shielding layer 21 may include a transition metal in a content ranging from 30 atom % or more and 60 atom % or less. The light-shielding layer 21 may include a transition metal in a content ranging from 35 atom % or more and 55 atom % or less. The first light-shielding layer 21 may include a transition metal in a content ranging from 40 atom % or more and 50 atom % or less.

The sum of the oxygen content and nitrogen content in the first light-shielding layer 21 may range from 40 atom % or more and 70 atom % or less. The sum of the oxygen content and nitrogen content in the first light-shielding layer 21 may range from 45 atom % or more and 65 atom % or less. The sum of the oxygen content and nitrogen content in the first light-shielding layer 21 may range from 50 atom % or more and 60 atom % or less.

The first light-shielding layer 21 may include oxygen in a content ranging from 20 atom % or more and 40 atom % or less. The first light-shielding layer 21 may include oxygen in a content ranging from 23 atom % or more and 33 atom % or less. The first light-shielding layer 21 may include oxygen in a content ranging from 25 atom % or more and 30 atom % or less.

The first light-shielding layer 21 may include nitrogen in a content ranging from 5 atom % or more and 20 atom % or less. The first light-shielding layer 21 may include nitrogen in a content ranging from 7 atom % or more and 17 atom % or less. The first light-shielding layer 21 may include nitrogen in a content ranging from 10 atom % or more and 15 atom % or less. In one embodiment, the first light-shielding layer 21 can help the light-shielding film 20 have excellent extinction properties.

The transition metal may include at least one of Cr, Ta, Ti and Hf. The transition metal may be Cr.

The second light-shielding layer may include nitrogen element in a content ranging from about 20 atom % to about 40 atom %, chromium element in a content ranging from about 30 atom % to about 50 atom % and oxygen element in a content ranging from about 20 atom % to about 40 atom %. In addition, the second light-shielding layer may further include carbon element in a content of less than 5 atom %.

The second light-shielding layer may include nitrogen element in a content of about 24 atom % to about 34 atom %, chromium element in a content of about 35 atom % to about 45 atom % and oxygen element in a content of about 26 atom % to about 36 atom %. In addition, the second light-shielding layer may further include carbon element in a content of less than 3 atom %.

The second light-shielding layer may include nitrogen element in a content of about 6 atom % to about 16 atom % chromium element in a content of about 26 atom % to about 46 atom %, oxygen element in a content of about 37 atom % to about 47 atom % and carbon element in a content of about 4 atom % to about 14 atom %.

The second light-shielding layer may include nitrogen element in a content of about 16 atom % to about 26 atom %, chromium element in a content of about 28 atom % to about 40 atom %, oxygen element in a content of about 27 atom % to about 37 atom % and carbon element in a content of about 3 atom % to about 13 atom %.

In addition, the first light-shielding layer may include nitrogen element in a content of about 10 atom % to about 30 atom %, chromium element in a content of about 60 atom % to about 90 atom % and oxygen element in a content of about 0.5 atom % to 10 atom %.

In addition, the first light-shielding layer may include carbon element in a content of less than 5 atom %.

The composition of the light-shielding film may be measured by X-ray photoelectron pectroscopy (XPS).

For example, a blank mask according to one embodiment is processed to a size of 15 mm in width and 15 mm in height to prepare a specimen. Next, the specimen is placed in K-Alpha model manufactured by Thermo Scientific (thermofisher.com/content/sfs/brochures/BR52586_E_0714M_K-AlphaPlus_web_H_2.pdf) to measure the composition of the blank mask, and an area measuring 4 mm wide and 2 mm long located in the center of the specimen may be etched with argon gas. During the etching time for each layer, the vacuum level in the measuring equipment was 1.0×10⁻⁸ mbar, the X-ray source was Monochromator A1 Kα (1486.6 eV), the anode electric power was 72 W, the anode voltage is 12 kV, and the argon ion beam voltage may be 1 kV.

In addition, in the etching time of the light-shielding film, the composition data from about 0 seconds to about 30 seconds is typically inaccurate data, so it may be excluded from the composition of the light-shielding film.

The thickness of the first light-shielding layer 21 may range from about 250 Å to about 650 Å. The thickness of the first light-shielding layer 21 may range from about 350 Å to about 600 Å. The thickness of the first light-shielding layer 21 may range from about 400 Å to about 550 Å. In this case, the first light-shielding layer 21 may help the light-shielding film 20 effectively block exposure light.

The thickness of the second light-shielding layer 22 may range from about 30 Å to about 200 Å. The thickness of the second light-shielding layer 22 may range from about 30 Å or more and about 100 Å. The thickness of the second light-shielding layer 22 may range from about 40 Å to about 80 Å. In this case, the second light-shielding layer 22 may improve the extinction characteristics of the light-shielding film 20 and may help to more precisely control the side surface profile of a light-shielding pattern film 25 formed during patterning of the light-shielding film 20.

A ratio of the thickness of the second light-shielding layer 22 to the thickness of the first light-shielding layer 21 may range from about 0.05 to about 0.3. The ratio of the thickness of the second light-shielding layer 22 to the thickness of the first light-shielding layer 21 may range from about 0.07 to about 0.25. The ratio of the thickness of the second light-shielding layer 22 to the thickness of the first light-shielding layer 21 may range from about 0.1 to about 0.2.

In one embodiment, the light-shielding film 20 has sufficient extinction characteristics and may more precisely control the side surface profile of a light-shielding pattern film 25 formed during patterning of the light-shielding film 20.

The content of a transition metal in the second light-shielding layer 22 may be larger than the content of a transition metal in the first light-shielding layer 21.

To more precisely control the side surface profile of the light-shielding pattern film 25 formed by pattering the light-shielding film 20 and to ensure that the reflectance of the surface of the light-shielding film 20 for inspection light in defect inspection has a value suitable for inspection, in one embodiment, the second light-shielding layer 22 may be required to have a larger transition metal content than the first light-shielding layer 21.

In one embodiment, recovery, recrystallization, and grain growth may occur in a transition metal contained in the second light-shielding layer 22 during the heat treatment of the formed light-shielding film 20. If grain growth occurs in the second light-shielding layer 22 containing a high content of a transition metal, the illuminance characteristics of the surface of the light-shielding film 20 may excessively change due to excessively grown transition metal particles. This may cause an increase in the number of pseudo defects detected when defects on the surface of the light-shielding film 20 are inspected with high sensitivity.

The light-shielding film 20, may have a transmittance of about 1% to about 2% for light with a wavelength of 193 nm. The light-shielding film 20 may have a transmittance of about 1.3% to about 2% for light with a wavelength of 193 nm. The light-shielding film 20 may have a transmittance of about 1.4% to about 2% for light with a wavelength of 193 nm.

The light-shielding film 20 may have an optical density of about 1.8 to about 3. The light-shielding film 20 may have an optical density of about 1.9 to about 3.

In one embodiment, a thin film containing the light-shielding film 20 may effectively suppress the transmission of exposure light.

As shown in FIG. 3, the blank mask 100 according to one embodiment may further include a phase shift film 30.

The phase shift film 30 may be disposed between the light-transmissive substrate 10 and the light-shielding film 20. The phase shift film 30 may be a thin film that attenuates the light intensity of penetrating exposure light and adjusts a phase difference to substantially suppress the diffracted light occurring at the edge of a pattern.

The phase shift film 30 may have a phase difference of about 170° to about 190° for light with a wavelength of 193 nm. The phase shift film 30 may have a phase difference of about 175° to about 185° for light with a wavelength of 193 nm.

The phase shift film 30 may have a transmittance of about 3% to about 10% for light with a wavelength of 193 nm. The phase shift film 30 may have a transmittance of about 4% to about 8% for light with a wavelength of 193 nm. In this case, the resolution of a photomask 200 containing the phase shift film 30 may be improved.

The phase shift film 30 may include a transition metal and silicon. The phase shift film 30 may include a transition metal, silicon, oxygen and nitrogen. The transition metal may be molybdenum.

A hard mask may be placed on the light-shielding film 20. The hard mask may function as an etching mask film when etching the pattern of the light-shielding film 20. The hard mask may include silicon, nitrogen and oxygen.

As shown in FIG. 4, a photomask 200 according to another embodiment includes a light-transmissive substrate 10; and a light-shielding pattern film 25 disposed on the light-transmissive substrate 10.

The light-shielding pattern film 25 includes a transition metal and at least one of oxygen and nitrogen.

The light-shielding pattern film 25 may be formed by patterning the light-shielding film 20 of the blank mask 100 described above.

The description of the physical properties, composition and structure of the light-shielding pattern film 25 is omitted as it overlaps with the description of the light-shielding film 20 of the blank mask 100 provided above.

A method of fabricating the blank mask 100 according to one embodiment includes a step of forming the light-shielding film 20 on the light-transmissive film. The light-shielding film 20 may be formed by a sputtering process.

The method may include a preparation step of installing a light-transmissive substrate and a sputtering target in a sputtering chamber such that a distance between the light-transmissive substrate and the sputtering target is 260 mm or more and 300 mm or less.

The method of fabricating the blank mask 100 according to one embodiment may include a deposition step of injecting gas into the sputtering chamber, applying electric power to the sputtering target and rotating the light-transmissive substrate at 25 rpm or more to form a light-shielding film 20.

The deposition step may include a first light-shielding layer formation process of forming a first light-shielding layer on the light-transmissive substrate; and a second light-shielding layer formation process of forming a second light-shielding layer on the first light-shielding layer.

After the sputtering process proceeds, a heat treatment process may proceed.

The heat treatment step may be performed at about 200° C. to about 400° C.

The heat treatment step may be performed for about 5 minutes to about 30 minutes.

In addition, the method of fabricating the blank mask 100 according to another embodiment may further include a step of cooling the light-shielding film 20 that has been subjected to the heat treatment process.

The sputtering target may be selected considering the composition of the light-shielding film 20 to be formed. The sputtering target may be applied with a single target containing a transition metal. The sputtering target may be applied with two or more targets including one target containing a transition metal. The target containing a transition metal may contain 90 atom % or more of a transition metal. The target containing a transition metal may contain 95 atom % or more of a transition metal. The target containing a transition metal may include 99 atom % of a transition metal.

The transition metal may include at least one of Cr, Ta, Ti and Hf. The transition metal may include Cr.

In the deposition step, a rotation speed of the light-transmissive substrate may be 25 rpm or more. The rotation speed may be 30 rpm or more. The rotation speed may be 100 rpm or less. In this case, a thickness variation in an in-plane direction of the formed light-shielding film 20 may be effectively reduced. In addition, the surface roughness characteristics of each sector within the surface of the light-shielding film 20 may be adjusted within a range preset in one embodiment.

The atmospheric gas may include inert gas, reactive gas and sputtering gas. The inert gas does not contain elements constituting an element formed into a thin film. The reactive gas may contain elements formed into the thin film.

The sputtering gas ionizes in a plasma atmosphere and collides with a target. The inert gas may include helium.

The reactive gas may include a gas containing nitrogen element. The gas containing the nitrogen element may be, for example, N₂, NO, NO₂, N₂O, N₂O₃, N₂O₄, N₂O₅ or the like. The reactive gas may include a gas containing an oxygen element.

The gas containing the oxygen element may be, for example, O₂. The reactive gas may include a gas containing nitrogen element and a gas containing oxygen element. The reactive gas may include a gas containing both nitrogen element and oxygen element. The gas containing both the nitrogen element and the oxygen element may be, for example, NO, NO₂, N₂O, N₂O₃, N₂O₄, N₂O₅, or the like.

In addition, the reactive gas containing carbon and oxygen may be CO₂.

The sputtering gas may be Ar gas.

A power source that applies power to the sputtering target may be either DC power or RF power.

In the process of forming the first light-shielding layer 21, electric power applied to the sputtering target may range from about 1.5 kW to about 2.5 k. In the process of forming the first light-shielding layer 21, electric power applied to the sputtering target may range from about 1.6 kW to about 2 kW.

In the process of forming the first light-shielding layer 21, a ratio of the flow rate of reactive gas to the flow rate of inert gas of atmospheric gas may range from about 1.5 to about 3. The flow rate ratio may range from about 1.8 to about 2.7. The flow rate ratio may range from about 2 to about 2.5.

A ratio of oxygen content to nitrogen content contained in the reactive gas may range from about 1.5 to about 4. The ratio of oxygen content to nitrogen content contained in the reactive gas may range from about 2 to about 3. The ratio of oxygen content to nitrogen content contained in the reactive gas may range from about 2.2 to about 2.7.

In one embodiment, the first light-shielding layer 21 may help the light-shielding film 20 have sufficient extinction properties. In addition, the side surface profile of the light-shielding pattern film 25 formed through patterning of the light-shielding film 20 may help to obtain a nearly vertical shape from the light-transmissive substrate 10 by improving the etching speed of the first light-shielding layer 21.

A deposition time of the first light-shielding layer 21 may range from about 200 seconds to about 300 seconds. The deposition time of the first light-shielding layer 21 may range from about 210 seconds to about 240 seconds. In this case, the first light-shielding layer 21 may help the light-shielding film 20 have sufficient extinction properties.

In the deposition process of the second light-shielding layer 22, an electric power of about 1 kW to about 2 KW may be applied to the sputtering target. In the deposition process of the second light-shielding layer 22, an electric power of about 1.2 kW to about 1.7 kW may be applied to the sputtering target.

In the deposition process of the second light-shielding layer 22, a ratio of the flow rate of the reactive gas to the flow rate of the inert gas in the atmospheric gas may range from about 0.3 to about 0.8. The flow rate ratio may range from about 0.4 to about 0.6.

In the deposition process of the second light-shielding layer 22, a ratio of oxygen content to nitrogen content contained in the reactive gas may be less than about 0.3. The ratio of oxygen content to nitrogen content contained in the reactive gas may be less than about 0.1. The ratio of oxygen content to nitrogen content contained in the reactive gas may be greater than 0.001. Since the second light-shielding layer 22 is formed as described, the light-shielding film 20 may have stable extinction properties.

A deposition time of the second light-shielding layer 22 may range from about 10 seconds to about 30 seconds. The deposition time of the second light-shielding layer 22 may range from about 15 seconds to about 25 seconds. In this case, the second light-shielding layer 22 may suppress the transmission of exposure light.

In the heat treatment step, multiple zones on the surface of the light-shielding film 20 may be each independently heat-treated at controlled temperatures. Specifically, a heater may be installed for each zone of the surface of the light-shielding film 20. The heater of each zone may be installed on the side of the light-transmissive substrate.

The temperature of the heater for each zone may be each independently controlled within a range of about 200° C. to 400° C.

After the heat treatment step, the blank mask 100 may be subjected to a cooling step for 2 minutes. In this case, the grain growth of transition metal particles due to residual heat in the light-shielding film 20 may be effectively prevented.

In the cooling step, the cooling rate of the blank mask 100 according to another embodiment may be controlled by installing pins with a preset length on each corner of a cooling plate, and placing the blank mask 100 on the pins so that the substrate faces the cooling plate.

In the cooling step, a cooling temperature applied to the cooling plate may range from about 10° C. to about 30° C. The cooling temperature may range from about 15° C. to about 25° C.

In the cooling step, a separation distance between the blank mask 100 according to another embodiment and the cooling plate may range from about 0.01 mm to about 30 mm. The separation distance may range from 0.05 mm or more and 5 mm or less. The separation distance may range from 0.1 mm or more and 2 mm or less.

The cooling step may be performed for about 1 minute to about 10 minutes. The cooling step may be performed for about 3 minutes to about 7 minutes.

Next, the cooled light-shielding film 20 may be cleaned. The cleaning process may include an ultraviolet irradiation process and/or a rinse process.

The ultraviolet irradiation process may include a step of irradiating ultraviolet rays to the light-shielding film 20.

Ultraviolet rays used in the ultraviolet irradiation process may be vacuum ultraviolet rays. Ultraviolet rays used in the ultraviolet irradiation process may be ultraviolet rays with a peak wavelength of about 100 nm to about 190 nm.

The ultraviolet irradiation process may be performed under a relative humidity condition of about 30% to about 60% at room temperature. The ultraviolet irradiation process may be performed under a relative humidity condition of about 40% to about 50% at room temperature.

In the ultraviolet irradiation process, an output of ultraviolet rays irradiated onto the light-shielding film 20 may range from about 5 mW/cm² to about 100 mW/cm². In the ultraviolet irradiation process, the output of ultraviolet rays irradiated onto the light-shielding film 20 may range from about 10 mW/cm² to about 70 mW/cm².

In the ultraviolet irradiation process, an irradiation time of the ultraviolet rays onto the light-shielding film 20 may range from about 10 seconds to about 10 minutes. In the ultraviolet irradiation process, the irradiation time of the ultraviolet rays onto the light-shielding film 20 may range from about 10 seconds to about 5 minutes. In the ultraviolet irradiation process, the irradiation time of the ultraviolet rays onto the light-shielding film 20 may range from about 1 minute to about 10 minutes. In the ultraviolet irradiation process, the irradiation time of the ultraviolet rays onto the light-shielding film 20 may range from about 10 seconds to about 1 minute.

In addition, in the ultraviolet irradiation process, nitrogen gas (N₂) or oxygen gas (O₂) may be used as supplied from an atmospheric gas.

The rinse process includes a step of treating the light-shielding film 20 with a cleaning solution. The cleaning solution may include at least one of deionized water, hydrogen water, ozone water and carbonated water. The cleaning solution may include the carbonated water.

In the carbonated water, the concentration of carbonic acid may range from about 500 mg/ [symbol] to about 5000 mg/ [symbol] . In the carbonated water, the concentration of carbonic acid may range from about 1000 mg/ [symbol] to about 3000 mg/ [symbol] .

In the ozone water, the concentration of ozone may range from about 50 mg/ [symbol] to about 2000 mg/ [symbol] . In the ozone water, the concentration of ozone may range from about 100 mg/ [symbol] to about 1000 mg/ [symbol] .

In the hydrogen water, the concentration of hydrogen may range from about 0.1 mg/ [symbol] to about 10 mg/ [symbol] . In the hydrogen water, the concentration of hydrogen may range from about 0.5 mg/ [symbol] to about 5 mg/ [symbol] .

The step of treating with the cleaning solution may include a step of immersing the blank mask 100 according to one embodiment in the cleaning solution. The step of treating with the cleaning solution may include a step of spraying and flowing the cleaning solution on the light-shielding film 20.

In the step of treating with the cleaning solution, a process time may range from about 1 minute to about 10 minutes. In the step of treating with the cleaning solution, the process time may range from about 2 minutes to about 7 minutes.

Next, in the step of treating with the cleaning solution, the light-shielding film 20 may be irradiated with ultraviolet rays. That is, the rinse process and the ultraviolet irradiation process may be performed at the same time. After the ultraviolet irradiation process, the rinse process may be performed. Here, during performing the rinse process, the light-shielding film 20 may be irradiated with ultraviolet rays in a manner similar to the ultraviolet irradiation process.

After the rinse process, the blank mask 100 according to one embodiment may be dried.

As shown in FIG. 6, the thickness of the light-shielding film 20 may be changed in the cleaning process. That is, in the cleaning process, a portion of the light-shielding film 20 may be removed so that the thickness of the light-shielding film 20 may be reduced. In the cleaning process, a thickness change (ΔT) in the light-shielding film 20 is a difference between the thickness before the cleaning process and the thickness after the cleaning process.

In the cleaning process, the thickness change in the light-shielding film 20 may be less than about 15 nm. In the cleaning process, the thickness change in the light-shielding film 20 may be less than about 5 nm. In the cleaning process, the thickness change in the light-shielding film 20 may be less than about 4 nm. In the cleaning process, the thickness change in the light-shielding film 20 may be less than about 3 nm. In the cleaning process, the thickness change in the light-shielding film 20 may be less than about 2.5 nm. In the cleaning process, the thickness change in the light-shielding film 20 may be less than about 2 nm. In the cleaning process, the thickness change in the light-shielding film 20 may be less than about 1.5 nm.

In the cleaning process, the thickness change in the light-shielding film 20 may range from about 0.3 nm to about 3 nm or about 0.1 nm to about 1 nm.

In the cleaning process, the thickness change in the light-shielding film 20 may range from about 0.1 nm to about 5 nm. In the cleaning process, the thickness change in the light-shielding film 20 may range from about 0.2 nm to about 5 nm. In the cleaning process, the thickness change in the light-shielding film 20 may range from about 0.3 nm to about 5 nm. In the cleaning process, the thickness change in the light-shielding film 20 may range from about 0.1 nm to about 3 nm. In the cleaning process, the thickness change in the light-shielding film 20 may range from about 0.2 nm to about 3 nm. In the cleaning process, the thickness change in the light-shielding film 20 may range from about 0.3 nm to about 3 nm.

In the cleaning process, the thickness change in the light-shielding film 20 may range from about 3 nm to about 15 nm. In the cleaning process, the thickness change in the light-shielding film 20 may range from about 3 nm to about 8 nm. In the cleaning process, the thickness change in the light-shielding film 20 may range from about 5 nm to about 15 nm.

In the cleaning process, the thickness of the light-shielding film 20 in the deposition process may be determined in consideration of the thickness change in the light-shielding film 20.

In the cleaning process, the thickness change in the light-shielding film 20 is the thickness change in the second light-shielding layer 22.

In the cleaning process, the optical properties of the light-shielding film 20 can be changed within appropriate ranges because the thickness change in the light-shielding film 20 has an appropriate range as described above.

In the cleaning process, since the thickness change in the light-shielding film 20 is as described above, the change in optical properties of the light-shielding film 20 may be minimized.

In the cleaning process, the transmittance of the light-shielding film 20 may be changed. The transmittance change in the light-shielding film 20 is a difference between the transmittance before the cleaning process and the transmittance after the cleaning process. The transmittance of the light-shielding film 20 may be measured by light in a wavelength range of about 193 nm.

In the cleaning process, the transmittance change in the light-shielding film 20 may be less than about 0.03%. In the cleaning process, the transmittance change in the light-shielding film 20 may be less than about 0.02%. In the cleaning process, the transmittance change in the light-shielding film 20 may be less than about 0.01%. In the cleaning process, the transmittance change in the light-shielding film 20 may be less than about 0.007%. In the cleaning process, the transmittance change in the light-shielding film 20 may be less than about 0.005%. In the cleaning process, the transmittance change in the light-shielding film 20 may be less than about 0.003%.

In the cleaning process, the transmittance change in the light-shielding film 20 may range from about 0.005% to about 0.02%.

In the cleaning process, a minimum transmittance change value in the light-shielding film 20 may be about 0.00001%.

In the cleaning process, since the transmittance change in the light-shielding film 20 is as described above, the light-shielding film 20 may reduce a difference in transmittance for each position. Accordingly, the blank mask 100 according to one embodiment may provide a precise photo mask.

In the cleaning process, the optical density of the light-shielding film 20 may be changed. The optical density change in the light-shielding film 20 may be a difference between the optical density before the cleaning process and the optical density after the cleaning process. The optical density may be measured with an optical density meter such as Linshang LS117 (linshangtech.com/product/LS117).

In the cleaning process, the optical density change in the light-shielding film 20 may be less than about 0.1. In the cleaning process, the optical density change in the light-shielding film 20 may be less than about 0.07. In the cleaning process, the optical density change in the light-shielding film 20 may be less than about 0.05. In the cleaning process, the optical density change in the light-shielding film 20 may be less than about 0.03. In the cleaning process, the optical density change in the light-shielding film 20 may be less than about 0.02.

In the cleaning process, the optical density change in the light-shielding film 20 may range from about 0.01 to about 0.08.

In the cleaning process, since a change in the optical density of the light-shielding film 20 is as described above, the light-shielding film 20 may reduce an optical density deviation for each position. Accordingly, the blank mask 100 according to one embodiment may provide a precise photo mask.

In the cleaning process, the reflectance of the light-shielding film 20 may be changed. The reflectance change in the light-shielding film 20 is a difference between the reflectance before the cleaning process and the reflectance after the cleaning process. The reflectance may be measured by light in a wavelength range of about 193 nm.

In the cleaning process, the reflectance change in the light-shielding film 20 may be less than about 0.5%. In the cleaning process, the reflectance change in the light-shielding film 20 may be less than about 0.4%. In the cleaning process, the reflectance change in the light-shielding film 20 may be less than about 0.3%. In the cleaning process, the reflectance change in the light-shielding film 20 may be less than about 0.2%.

In the cleaning process, a minimum reflectance change value of the light-shielding film 20 may be about 0.01%.

In the cleaning process, since the reflectance change in the light-shielding film 20 is as described above, the light-shielding film 20 may reduce a reflectance deviation for each position. Accordingly, the blank mask 100 according to one embodiment may provide a precise photo mask.

An ion concentration on the surface of the blank mask 100 according to another embodiment may be low.

On the entire surface of the blank mask 100 according to one embodiment, the content of halogen ions may be less than 0.15 ng/cm². On the entire surface of the blank mask 100 according to another embodiment, the content of halogen ions may be less than 0.10 ng/cm². On the entire surface of the blank mask 100 according to another embodiment, the content of halogen ions may be less than 0.07 ng/cm². On the entire surface of the blank mask 100 according to another embodiment, the content of halogen ions may be less than 0.05 ng/cm².

The halogen ions may include chlorine ions.

On the entire surface of the blank mask 100 according to one embodiment, the content of nitrogen-based ions may be less than 3 ng/cm². On the entire surface of the blank mask 100 according to another embodiment, the content of nitrogen-based ions may be less than 2.5 ng/cm². On the entire surface of the blank mask 100 according to another embodiment, the content of nitrogen-based ions may be less than 2 ng/cm². On the entire surface of the blank mask 100 according to another embodiment, the content of nitrogen-based ions may be less than 1.8 ng/cm². On the entire surface of the blank mask 100 according to another embodiment, the content of nitrogen-based ions may be less than 1.5 ng/cm².

The nitrogen-based ions may include nitrite ions, nitrate ions and ammonia.

On the entire surface of the blank mask 100 according to one embodiment, the content of sulfur-based ions may be less than about 0.2 ng/cm². On the entire surface of the blank mask 100 according to another embodiment, the content of sulfur-based ions may be less than about 0.17 ng/cm². On the entire surface of the blank mask 100 according to another embodiment, the content of sulfur-based ions may be less than about 0.1 ng/cm². On the entire surface of the blank mask 100 according to another embodiment, the content of sulfur-based ions may be less than about 0.07 ng/cm².

The sulfur-based ions may include sulfate ions.

In addition, the content of acetate on the entire surface of the blank mask 100 according to one embodiment may be less than 0.02 ng/cm². On the entire surface of the blank mask 100 according to another embodiment, the content of oxalate may be less than 0.02 ng/cm². On the entire surface of the blank mask 100 according to another embodiment, the content of sodium may be less than 0.02 ng/cm². On the entire surface of the blank mask 100 according to another embodiment, the content of potassium may be less than 0.02 ng/cm². On the entire surface of the blank mask 100 according to another embodiment, the content of magnesium may be less than 0.02 ng/cm². On the entire surface of the blank mask 100 according to another embodiment, the content of calcium may be less than 0.02 ng/cm².

Since the surface ion concentration of the blank mask 100 according to one embodiment is low as described above, defects may be suppressed, and a photomask of improved quality may be provided.

In the blank mask 100 according to one embodiment, the surface ion concentration may be measured by ion chromatography. The blank mask 100 according to another embodiment is immersed in deionized water, ions are eluted for a sufficient time, and the content of eluted ions may be measured.

In the blank mask 100 according to another embodiment, the thickness change in the light-shielding film 20 measured by the following method may be less than about 2 nm.

### Measurement Method

The light-shielding film 20 is immersed in carbonated water with a carbonate concentration of about 2000 mg/C for about 10 minutes. A thickness change in the light-shielding film 20 is a difference between the thickness of the light-shielding film 20 before immersion and the thickness of the light-shielding film 20 after immersion.

The thickness change may be less than about 10 nm. The thickness change may be less than about 7 nm. The thickness change may be less than about 5 nm. The thickness change may be less than about 4 nm. The thickness change may be less than about 3 nm. The thickness change may be less than about 2.5 nm. The thickness change may be less than about 2 nm. The thickness change may be less than about 1.55 nm.

The thickness change may range from about 3 nm to about 15 nm. The thickness change may range from about 3 nm to about 8 nm. The thickness change may range from about 7 nm to about 15 nm

The thickness change may v about 0.1 nm to about 10 nm. The thickness change may range from about 0.1 nm to about 7 nm. The thickness change may range from about 0.1 nm to about 5 nm. The thickness change may range from about 0.1 nm to about 4 nm. The thickness change may range from about 0.1 nm to about 3 nm. The thickness change may range from about 0.1 nm to about 2.5 nm. The thickness change may range from about 0.1 nm to about 2 nm. The thickness change may range from about 0.1 nm to about 1.55 nm.

The thickness change may range from 0.3 nm to 3 nm or from 0.1 nm to 1 nm. The thickness change is a thickness change in the second light-shielding layer 22.

In addition, the transmittance of the blank mask 100 according to one embodiment may be changed. The transmittance change may be derived by the above measurement method. The transmittance change is a difference between the transmittance of the light-shielding film 20 before immersion and the transmittance of the light-shielding film 20 after immersion.

The transmittance change may be less than about 0.3%. The transmittance change may be less than about 0.2%. The transmittance change may be less than about 0.1%. The transmittance change may be less than about 0.05%. A minimum value of the transmittance change may be about 0.00001%.

The transmittance change may range from about 0.003% to about 0.02%.

In addition, the optical density of the blank mask 100 according to one embodiment may be changed. The optical density change may be derived by the above measurement method.

The optical density change may be less than 0.1. The optical density change may be less than 0.08. The optical density change may be less than 0.07. The optical density change may be less than 0.05. The optical density change may be less than 0.03. The optical density change may be less than 0.02. A minimum value of the optical density change may be about 0.0001.

The optical density change may range from about 0.01 to about 0.07. The optical density change may range from about 0.01 to about 0.04. The optical density change may range from about 0.03 to about 0.07

In addition, the reflectance of the blank mask 100 according to another embodiment may be changed. The reflectance change may be derived by the above measurement method.

The reflectance change may be less than about 0.3%. The reflectance change may be less than about 0.2%. The reflectance change may be less than about 0.1%. The reflectance change may be less than about 0.08%. The reflectance change may be less than about 0.05%. A minimum of the reflectance change may be about 0.0001%.

After being immersed in the carbonated water as described above, the blank mask 100 according to one embodiment exhibits a low thickness change, transmittance change, optical density change and reflectance change. Accordingly, in the cleaning process and the like of the photomask fabrication process, a change in the optical properties of the blank mask 100 according to one embodiment may be minimized.

A method of fabricating a semiconductor device according to one embodiment includes a step of placing a light source, a photomask 200 and a semiconductor wafer coated with a resist film; an exposure step of selectively transmitting and emitting light, incident from the light source, onto a semiconductor wafer through the photomask 200; and a development step of developing a pattern on the semiconductor wafer.

The photomask 200 includes the light-transmissive substrate 10; and the light-shielding pattern film 25 disposed on the light-transmissive substrate 10.

The light-shielding pattern film 25 includes a transition metal and at least one of oxygen, nitrogen and carbon.

In the preparation step, the light source is a device capable of generating short-wavelength exposure light. The exposure light may be light having a wavelength of 200 nm. The exposure light may be ArF light having a wavelength of 193 nm.

A lens may be additionally disposed between the photomask 200 and the semiconductor wafer. The lens has the function of reducing the circuit pattern shape on the photomask 200 and transferring it onto the semiconductor wafer. The lens is not limited as long as it can be generally applied to an ArF laser light semiconductor wafer exposure process. For example, the lens may be a lens made of calcium fluoride (CaF₂).

In the exposure step, exposure light may be selectively transmitted onto the semiconductor wafer through the photomask 200. In this case, chemical degeneration may occur in a resist film part on which exposure light is incident.

In the development step, the semiconductor wafer that has been subjected to the exposure step may be treated with a developing solution to develop a pattern on the semiconductor wafer. When the applied resist film is a positive resist, a resist film part on which exposure light is incident may be dissolved by the developing solution. When for example the applied resist film is a negative resist, a resist film part on which exposure light is not incident may be dissolved by the developing solution. The resist film is formed into a resist pattern by treatment with the developing solution. A pattern may be formed on the semiconductor wafer using the resist pattern as a mask.

A description of the photomask 200 is omitted as it overlaps with the previous content.

Hereinafter, specific examples are described in more detail.

### Example 1

A light-transmissive substrate made of quartz measuring 6 inches wide, 6 inches long, and 0.25 inches thick was placed in a chamber of DC sputtering equipment. A chrome target was placed in the chamber so that the T/S distance was 200 mm and the angle between the substrate and the target was 45 degrees. The temperature of the chamber was elevated to about 400° C.

Next, atmospheric gas mixed with 21 vol % Ar, 11 vol % N₂, 32 vol % CO₂ and 36 vol % He was introduced into the chamber, an electric power of 1.85 KW was applied to a sputtering target, and a sputtering process was performed at a substrate rotation speed of 30 rpm for 250 seconds, thereby depositing a first light-shielding layer.

After depositing the first light-shielding layer, atmospheric gas mixed with 57 vol % Ar, 33 vol % N₂ and 10 vol % CO₂ was introduced into the chamber, an electric power of 1.5 kW was applied to the sputtering target, and a sputtering process was performed at a substrate rotation speed of 30 rpm for 45 seconds, so that a second light-shielding layer was deposited on the first light-shielding layer. As a result, a blank mask specimen forming was produced.

The specimen deposited with the second light-shielding layer was placed in a heat treatment chamber, and heat-treated at a heater temperature of about 300° C. for about 15 minutes.

A cooling plate having a cooling temperature of 23° C. was installed on the substrate of the heat-treated specimen. Next, cooling gas was injected through a nozzle at a flow rate of 50 sccm, and cooling was performed for 5 minutes. Helium was used as the cooling gas.

Next, vacuum ultraviolet rays with a wavelength of about 185 nm were irradiated at an intensity of about 40 mW/cm² for about 1 minute onto the upper surface of the light-shielding film in the chamber to which vacuum pressure was applied.

Next, carbonated water (carbonic acid concentration, 2000 mg/€) was flowed onto the light-shielding film that had undergone the ultraviolet ray process. At the same time, the vacuum ultraviolet rays were also irradiated onto the light-shielding film under the same conditions as above. The rinsing process using carbonated water was performed for about 1 minute.

Next, the cleaning solution containing carbonated water and hydrogen water (hydrogen concentration: 1.6 mg/ [symbol] ) in a ratio of about 1:1 was flowed onto the light-shielding film for about 30 seconds, and a surface cleaning process was performed.

Next, the blank mask according to this example was dried.

### Examples 2 to 4 and Comparative Example 1

The deposition and cleaning conditions of the second light-shielding layer are shown in Tables 1 and 2, and the remaining processes are the same as in Example 1. In ozone water, the concentration of ozone was about 200 mg/ [symbol] .

### Examples 5 to 8

A light-transmissive substrate made of quartz measuring 6 inches wide, 6 inches long, and 0.25 inches thick was placed in a chamber of DC sputtering equipment. A chrome target was placed in the chamber so that the T/S distance was 200 mm and the angle between the substrate and the target was 45 degrees. The temperature of the chamber was elevated to about 400° C.

Next, atmospheric gas mixed with 57 vol % Ar and 43 vol % N₂ was introduced into the chamber, an electric power of 1.35 KW was applied to a sputtering target, and a sputtering process was performed at a substrate rotation speed of 30 rpm for 430 seconds, thereby depositing a first light-shielding layer.

After depositing the first light-shielding layer, atmospheric gas mixed with 15 vol % Ar, 72 vol % N₂ and 13 vol % O₂ was in the chamber, an electric power of 1.85 KW was applied to a sputtering target, and a sputtering process was performed at a substrate rotation speed of 30 rpm for 210 seconds, so that a second light-shielding layer was deposited on the first light-shielding layer. As a result, a blank mask specimen was produced.

After depositing the light-shielding layer, a heat treatment process, a cooling process and a cleaning process were performed in the same manner as in Example 1.

In addition, in Examples 6 to 8, the depositing and cleaning conditions of the second light-shielding layer are shown in Tables 1 and 2 below, and the remaining processes were performed as in Example 5. In addition, in Comparative Examples 7 and 8, helium gas was applied in a ratio of about 34% by volume and about 24% by volume, respectively.

### Example 9

A light-transmissive substrate made of quartz measuring 6 inches wide, 6 inches long, and 0.25 inches thick was placed in a chamber of DC sputtering equipment. A chrome target was placed in the chamber so that the T/S distance was 200 mm and the angle between the substrate and the target was 45 degrees. The temperature of the chamber was elevated to about 400° C.

The chamber was filled with argon gas and nitrogen gas in a volume ratio of about 15:35. Next, a first-stage sputtering process was performed for about 30 seconds at a power of about 1.4 kW while maintaining the ratio of the argon gas and the nitrogen gas inside the chamber.

Next, the sputtering power increased from about 1.4 kW to about 1.8 kW, and a second-stage sputtering process was performed for about 80 seconds while flowing argon gas, nitrogen gas, and carbon dioxide in a volume ratio of 2:2:1 into the chamber.

Next, a third-stage sputtering process was performed for about 100 seconds. In the third-stage sputtering process, the volume ratio of the gases introduced into the chamber was respectively adjusted such that the volume ratio of argon gas, helium gas, nitrogen gas, oxygen gas and carbon dioxide introduced into the chamber gradually changed from about 2:2:0:0:1 to about 2:2:4:4:1. During the third-stage sputtering process, the sputtering power was continuously lowered from about 1.8 kW to about 1.4 kW.

Next, a fourth-stage sputtering process was performed for about 60 seconds. During the fourth-stage sputtering process, the sputtering power was maintained at about 1.4 kW. In addition, in the fourth-stage sputtering process, the volume ratio of the gases introduced into the chamber was respectively adjusted such that the volume ratio of argon gas, helium gas, nitrogen gas, oxygen gas and carbon dioxide introduced into the chamber gradually changed from about 2:2:4:4:1 to about 2:2:2:5:1.

After depositing the light-shielding layer, a heat treatment process, a cooling process, and a cleaning process were performed in the same manner as in Example 1.

TABLE 1

| | | | Carbon | | Sputter |
|---|---|---|---|---|---|
| | | Nitrogen | dioxide | Oxygen | target |
| | Ar | gas | gas | gas | electric |
| Classification | (vol %) | (vol %) | (vol %) | (vol %) | power (kW) |
| Example 1 | 57 | 33 | 10 | | 1.5 |
| Example 2 | 50 | 30 | 10 | 10 | 1.7 |
| Example 3 | 60 | 20 | 10 | 10 | 1.6 |
| Example 4 | 60 | 30 | 5 | 5 | 1.6 |
| Example 5 | 15 | 72 | | 13 | 1.85 |
| Example 6 | 20 | 68 | | 11 | 1.85 |
| Example 7 | 19 | 11 | 37 | | 1.85 |
| Example 8 | 18 | 20 | 30 | | 1.85 |
| Comparative | 40 | 30 | 15 | 15 | 1.8 |
| Example 1 | | | | | |

TABLE 2

| | UV process | | Cleaning | |
|---|---|---|---|---|
| Classification | time (min) | Rinse cleaning | time | Surface cleaning |
| Example 1 | 1 | Carbonated water | 1 | Carbonated water + hydrogen water 1:1 |
| Example 2 | 2 | Carbonated water | 1.5 | Carbonated water + hydrogen water 1:1 |
| Example 3 | 1.5 | Ozone water | 1 | Ozone water + hydrogen water 1:1 |
| Example 4 | 1 | Ozone water | 1.5 | Ozone water + hydrogen water 1:1 |
| Example 5 | 1 | Ozone water | 1 | Carbonated water + hydrogen water 1:1 |
| Example 6 | 1 | Ozone water | 1 | Carbonated water + hydrogen water 1:1 |
| Example 7 | — | Ozone water | 1 | Carbonated water + hydrogen water 1:1 |
| Example 8 | — | Ozone water | 1 | Carbonated water + hydrogen water 1:1 |
| Example 9 | — | Ozone water | 1 | Carbonated water + hydrogen water 1:1 |
| Comparative Example 1 | — | — | — | Deionized water |

### Evaluation Example

### 1. Surface Ion Concentration

Each of the blank masks manufactured in the examples and the comparative examples was placed in a clean bag, and about 100 ml of deionized water was added to the clean bag. Next, the clean bag containing each of the blank masks manufactured in the examples and the comparative examples was allowed to stand at about 90° C. for about 120 minutes. Next, the concentration of ions eluted from each of the blank masks manufactured in the examples and the comparative examples was analyzed using ion chromatography equipment (Dionex ICS-2100 manufactured by ThermoSCIENTIFIC), and the concentration of the eluted ions relative to the surface area of the blank mask is summarized in Table 3 below. Fluorine, acetate, formate, oxalate, sodium, potassium, magnesium and calcium were not detected.

### 2. Measurement of Thickness Change, Transmittance Change, Optical Density Change and Reflectance Change

In the light-shielding film before the cleaning and the light-shielding film after the cleaning, a thickness change, a transmittance change, an optical density change and a reflectance change were measured, and summarized in Table 4 below.

Each of the blank masks manufactured in the examples and the comparative examples was immersed for about 10 minutes in carbonated water with a carbonate concentration of about 2000 mg/ [symbol] .

In the light-shielding film before the immersion and the light-shielding film after the immersion, a thickness change, a transmittance change, an optical density change and a reflectance change were measured, and summarized in Table 5 below.

At 23 points of the light-shielding film, a thickness, a transmittance, an optical density and a reflectance were measured, and average values thereof were obtained.

The thickness, transmittance, optical density and reflectance of the light-shielding film were measured using MG-PRO manufactured by Nanoview.

The transmittance and the reflectance were measured for light in a wavelength of about 193 nm.

### 3. Light-Shielding Layer Composition

The composition of the light-shielding layer was measured by X-ray photoelectron spectroscopy (XPS).

Each of the blank masks manufactured in the examples and the comparative examples was processed to a size of 15 mm in width and 15 mm in height to prepare a specimen. Next, the specimen was placed in K-Alpha model manufactured by Thermo Scientific, and an area measuring 4 mm wide and 2 mm long located in the center of the specimen was etched with argon gas. During the etching time for each of the layers, the vacuum level in the measuring equipment was 1.0×10⁻⁸ mbar, the X-ray source was Monochromator A1 Kα (1486.6 eV), the anode electric power was 72 W, the anode voltage was 12 kV, and the argon ion beam voltage was 1 kV.

From an etching time of about 30 seconds to about 80 seconds, the compositions of the second light-shielding layers were measured using the above measurement equipment, as shown in Table 6 below.

In addition, from an etching time of about 30 seconds to about 84 seconds, the compositions of the light-shielding layers of Example 9 were measured using the above measurement equipment, as shown in Table 7 below.

TABLE 3

| Classifi- | Cl | NO₂ | NO₃ | SO₄ | NH₄ |
|---|---|---|---|---|---|
| cation | (ng/cm²) | (ng/cm²) | (ng/cm²) | (ng/cm²) | (ng/cm²) |
| Example 1 | 0.06 | 0.02 | 0.04 | 0.04 | 1.06 |
| Example 2 | 0.01 | 0.01 | 0.01 | 0.06 | 0.73 |
| Example 3 | 0.02 | 0.03 | 0.05 | 0.06 | 0.47 |
| Example 4 | 0.03 | 0.03 | 0.02 | 0.06 | 0.59 |
| Example 5 | 0.04 | 0.01 | 0.02 | 0.05 | 0.71 |
| Example 6 | 0.04 | 0.02 | 0.03 | 0.06 | 0.98 |
| Example 7 | 0.03 | 0.03 | 0.02 | 0.05 | 0.79 |
| Example 8 | 0.02 | 0.02 | 0.02 | 0.04 | 0.68 |
| Example 9 | 0.02 | 0.02 | 0.02 | 0.04 | 0.52 |
| Comparative | 0.15 | 0.11 | 0.12 | 0.15 | 1.88 |
| Example | | | | | |

TABLE 4

| | | | Optical | |
|---|---|---|---|---|
| | Thickness | Transmittance | density | Reflectance |
| Classification | change (nm) | change (%) | change | change (%) |
| Example 1 | 1.03 | 0.002 | 0.01 | 0.25 |
| Example 2 | 1.23 | 0.003 | 0.01 | 0.36 |
| Example 3 | 2.12 | 0.002 | 0.003 | 0.22 |
| Example 4 | 2.30 | 0.0025 | 0.005 | 0.28 |
| Example 5 | 0.3 | 0 | 0 | 0.01 |
| Example 6 | 0.5 | 0 | 0 | 0.01 |
| Example 7 | 11.3 | 0.01 | 0.0465 | 1.53 |
| Example 8 | 10.2 | 0.01 | 0.0423 | 1.42 |
| Example 9 | 5.1 | 0.005 | 0.0215 | 0.56 |
| Comparative | — | — | — | — |
| example | | | | |

TABLE 5

| | | | Optical | |
|---|---|---|---|---|
| | Thickness | Transmittance | density | Reflectance |
| Classification | change (nm) | change (%) | change | change (%) |
| Example 1 | 2.31 | 0.023 | 0.06 | 0.26 |
| Example 2 | 2.23 | 0.032 | 0.04 | 0.35 |
| Example 3 | 2.32 | 0.021 | 0.05 | 0.24 |
| Example 4 | 2.50 | 0.027 | 0.06 | 0.29 |
| Example 5 | 0.5 | 0 | 0 | 0.01 |
| Example 6 | 0.7 | 0 | 0 | 0.01 |
| Example 7 | 12.5 | 0.011 | 0.0485 | 1.54 |
| Example 8 | 11.4 | 0.0105 | 0.0435 | 1.37 |
| Example 9 | 5.6 | 0.063 | 0.236 | 0.58 |
| Comparative | 2.37 | 0.031 | 0.08 | 0.31 |
| example | | | | |

TABLE 6

| | N | Cr | C | O |
|---|---|---|---|---|
| Classification | (atom %) | (atom %) | (atom %) | (atom %) |
| Example 5 | 28.52 | 38.90 | — | 32.58 |
| Example 6 | 25.67 | 45.01 | — | 29.32 |
| Example 7 | 11.42 | 37.68 | 9.47 | 41.17 |
| Example 8 | 23.88 | 34.48 | 8.60 | 33.04 |

TABLE 7

| | N | Cr | C | O |
|---|---|---|---|---|
| Classification | (atom %) | (atom %) | (atom %) | (atom %) |
| 30 seconds | 20.15 | 36.39 | 2.65 | 40.80 |
| 42 seconds | 21.06 | 37.08 | 1.82 | 40.04 |
| 52 seconds | 21.95 | 37.10 | 1.76 | 39.18 |
| 63 seconds | 23.29 | 37.66 | 1.31 | 37.73 |
| 73 seconds | 24.60 | 38.69 | 1.40 | 35.30 |
| 84 seconds | 25.79 | 39.30 | 1.74 | 33.16 |

As summarized in Tables 3 to 7, the blank mask according to one embodiment has a low surface ion concentration, a low thickness change, a low transmittance change, a low optical density change and a low reflectance change.

### DESCRIPTION OF SYMBOLS

100: blank mask
10: light-transmissive substrate
20: light-shielding film
21: first light-shielding layer
22: second light-shielding layer
25: light-shielding pattern film
30: phase shift film
200: photomask

What is claimed is:

1. A method of fabricating a blank mask, the method comprising:
forming a light-shielding film on a light-transmissive substrate; and
cleaning the light-shielding film with a cleaning solution,
wherein in the cleaning, the light-shielding film has a thickness change of less than 15 nm.

2. The method according to claim 1, further comprising: forming a phase shift film on the light-transmissive substrate,
wherein the light-shielding film is formed on the phase shift film.

3. The method according to claim 1, wherein on an entire surface of the blank mask as measured by an ion elution of ions from the blank mask in deionized water, a content of halogen ions is less than 0.1 ng/cm², a content of nitrogen-based ions is less than 3 ng/cm², and a content of sulfur-based ions is less than 0.1 ng/cm².

4. The method according to claim 3, wherein the halogen ions comprise chlorine-based ions, the nitrogen-based ions comprise nitrite ions, nitrate ions and ammonia, and the sulfur-based ions comprise sulfate ions.

5. The method according to claim 1, wherein the cleaning solution comprises carbonated water.

6. The method according to claim 5, wherein in the cleaning, the light-shielding film has a transmittance change of less than 0.05%.

7. The method according to claim 6, wherein in the cleaning, the light-shielding film has an optical density change of less than 0.07.

8. The method according to claim 7, wherein in the cleaning, the light-shielding film has a reflectance change of less than 0.5%.

9. The method according to claim 1, wherein in the cleaning, the light-shielding film has a thickness change ranging from 0.3 nm to 3 nm.

10. The method according to claim 9, wherein the light-shielding film comprises:
a first light-shielding layer disposed on the light-transmissive substrate; and
a second light-shielding layer disposed on the first light-shielding layer,
wherein the second light-shielding layer comprises a nitrogen element in a content ranging from 20 atom % to 40 atom %, a chromium element in a content ranging from 30 atom % to 50 atom % and an oxygen element in a content ranging from 20 atom % to 40 atom %.

11. The method according to claim 10, wherein the first light-shielding layer comprises a nitrogen element in a content ranging from 10 atom % to 30 atom %, a chromium element in a content ranging from 60 atom % to 90 atom % and an oxygen element in a content ranging from 0.5 atom % to 10 atom %.

12. The method according to claim 10, wherein the second light-shielding layer comprises a carbon element in a content of less than 5 atom %.

13. A blank mask, comprising:
a light-transmissive substrate; and
a light-shielding film disposed on the light-transmissive substrate,
wherein on an entire surface of the blank mask, a content of halogen ions is less than 0.05 ng/cm², a content of nitrogen-based ions is less than 2 ng/cm², and a content of sulfur-based ions is less than 0.1 ng/cm².

14. The blank mask according to claim 13, wherein a thickness change in the light-shielding film measured by a measurement method below is less than 15 nm:
wherein, in the measurement method, the light-shielding film is immersed for 10 minutes in carbonated water with a carbonate concentration of 2000 mg/C, and the thickness change in the light-shielding film is a difference between a thickness of the light-shielding film before immersion and a thickness of the light-shielding film after immersion.

15. The blank mask according to claim 14, wherein the light-shielding film has a transmittance change of less than 0.05%, the light-shielding film has an optical density change of less than 0.07, and the light-shielding film has a reflectance change of less than 0.5%,
the transmittance change is a difference between a transmittance of the light-shielding film before immersion and a transmittance of the light-shielding film after immersion,
the optical density change is a difference between an optical density of the light-shielding film before immersion and an optical density of the light-shielding film after immersion, and
the reflectance change is a difference between a reflectance of the light-shielding film before immersion and a reflectance of the light-shielding film after immersion.

16. The blank mask according to claim 14, wherein the light-shielding film comprises:
a first light-shielding layer disposed on the light-transmissive substrate; and
a second light-shielding layer disposed on the first light-shielding layer,
wherein the second light-shielding layer comprises a nitrogen element in a content ranging from 20 atom % to 40 atom %, a chromium element in a content ranging from 30 atom % to 50 atom % and an oxygen element in a content ranging from 20 atom % to 40 atom %.

17. The blank mask according to claim 16, wherein the first light-shielding layer comprises a nitrogen element in a content of 10 atom % to 30 atom %, a chromium element in a content of 60 atom % to 90 atom % and an oxygen element in a content of 0.5 atom % to 10 atom %.

18. The blank mask according to claim 14, wherein the light-shielding film has a thickness change ranging from 0.3 nm to 3 nm.

19. The blank mask according to claim 14, wherein the light-shielding film has a thickness change ranging from 3 nm to 15 nm.

20. A photomask, comprising:
a light-transmissive substrate; and
a light-shielding film disposed on the light-transmissive substrate,
wherein on an entire outer surface of the light-shielding film of the photomask, a content of halogen ions is less than 0.05 ng/cm², a content of nitrogen-based ions is less than 2 ng/cm², and a content of sulfur-based ions is less than 0.1 ng/cm².
